(19) United States
(12) Patent Application Publication
(10) Pub. No.: US 2013/0013232 A1
(43) Pub. Date: Jan. 10, 2013

(54) SYSTEM AND METHOD FOR USE IN ELECTRIC POWER DISTRIBUTION SYSTEMS

(76) Inventors: Nawal Kishor Parwal, Suwanee, GA (US); Aleksandar Vukojevic, Atlanta, GA (US); Damon Lane Walker, Woodstock, GA (US)

(21) Appl. No.: 13/178,590

(22) Filed: Jul. 8, 2011

(51) Int. Cl. G06F 19/00; G01R 21/06

(52) U.S. Cl. 702/60

(57) ABSTRACT

A system for enhancing deferrable load management of a distribution transformer includes a memory device configured to store a plurality of operational measurements of a distribution transformer and at least one deferrable load. The system also includes a processor coupled in communication with the memory device. The processor is programmed to record a first operational measurement of the distribution transformer that is configured to transmit electric power to the at least one deferrable load. The processor is also programmed to record a second operational measurement of the at least one deferrable load. The processor is further programmed to determine a priority of energization of the at least one deferrable load within a queue as a function of at least one of the first operational measurement and the second operational measurement.

### BACKGROUND OF THE INVENTION

The subject matter disclosed herein relates generally to electric power distribution systems and, more specifically, to systems and methods for use in monitoring and controlling electric power delivery via distribution transformers.

Known electric power grids typically include power generation plants, transmission and distribution lines, transformers, and other devices that facilitate electric power transmission, and power delivery. After electric power is generated in the generating plants, it is transmitted for extended distances through the high voltage transmission lines to distribution substations. Transmission lines usually operate at voltage levels between approximately 115 kilovolts (kV) and approximately 765 kV. At the distribution substations, transformers reduce the high voltage at which the power has been transmitted to sub-transmission voltage levels that range from approximately 46 kV to approximately 69 kV, or to distribution voltage levels that range from approximately 12 kV to approximately 34.5 kV. Power is then transmitted through a feeder to an end customer, and before it reaches the end customer, the voltage is decreased to approximately 120V/240V by a distribution transformer.

Most known local distribution transformers typically deliver power to a number of residences that range from one home to twenty homes, depending upon the concentration of customer premises in a particular area. These known distribution transformers are rated between approximately 5 kilovolt-amperes (kVA) and approximately 500 kVA. A localized power distribution system for a given area includes one or more distribution transformers. Therefore, distribution transformers are essential for delivery of electric power to customer premises and replacement costs and maintenance costs for distribution transformers may be a significant factor in the overall cost of power distribution.

Most known distribution transformers are continuously in service. Therefore grid operators endeavor to maintain electric power delivery within the ratings of the transformers. However, on occasion, some known distribution transformers may exceed their ratings, thereby possibly resulting in a reduction in the useful lifespan of the transformers. Although many of the known distribution transformers are capable of supporting electric loads significantly higher than their rated capacity, the service life and the mean time between failures (MTBF) of such distribution transformers is adversely impacted under such load conditions. Specifically, as transformer loading increases the temperature of the transformer windings also increases, which in turn increases the temperature of the transformer insulation. A breakdown of the transformer's insulation, such as from the increased temperature, decreases the useful life of the transformer, and increases the potential of a transformer failure.

In many known geographic regions, use of electric vehicles is increasing, and as a result, power demand will likely increase in the form of electrical power used to charge batteries or other energy storage devices used in such vehicles. The electric power drawn by an electric vehicle through a charging station increases power transmission through the power grid components, for example, the local distribution transformers. For example, a majority of motorists return to a residence from a place of business in the early evening. It is expected that a majority of electric vehicle owners will desire to charge their electric vehicle upon returning to their residence from their place of business. Charging an electric vehicle is likely to create an individual residential electrical load that is substantially larger than other individual residential electrical loads, for example, lighting and small appliances. Furthermore, if multiple residences served by a single distribution transformer include a vehicle charging station, the power demand created by charging a plurality of electric vehicles from one distribution transformer may cause the distribution transformer to overload, thereby reducing the useful life of the distribution transformer. Generally, charging of electric vehicles is a deferrable load, i.e., a load that can deferred for a finite period of time with appropriate constraints. Other deferrable loads include pool pumps, battery energy storage systems (BESS), and smart devices, e.g., smart clothes driers.

Many known electric power grid systems use smart grid technologies, or systems, that facilitate two-way metering communications between energy consumers and their associated utilities. In addition, many operators of known electric power grids and smart grid systems use a demand response management system (DRMS) to facilitate load management at distribution voltage levels. However, these known DRMSs do not have sufficient granularity at the distribution transformer level and may not address local conditions at a particular distribution transformer. Specifically, these DRMSs facilitate management of large electric loads or grouped pluralities of small electric loads, and are not suitable for addressing distribution transformer level requirements. Moreover, most known DRMSs have a duty cycle that corresponds to an hourly level, and not in real-time. Furthermore, due to stringent regulatory requirements with respect to the reportable number of DR events per year, utilities may endeavor to reduce the number of reported events, and therefore may miss opportunities for investigation.

Moreover, smart grid systems, in conjunction with DRMSs, generate a voluminous amount of grid operating data transmitted through the communication networks from remote devices to the associated utility's “back office”. While this data may be useful for facilitating utilities to identify any potential issues on the grid and make proper decisions, the amount of collected data is very large, and there is a significant latency associated with data processing and analysis after such data collection. Therefore, known DRMSs do not facilitate managing this data proactively and appropriately act on it in a timely manner. Furthermore, the large data volumes require increased bandwidth of the communication channels to transmit this data.

### BRIEF DESCRIPTION OF THE INVENTION

In one aspect, a system for enhancing deferrable load management of a distribution transformer is provided. The system includes a memory device configured to store a plurality of operational measurements of a distribution transformer and at least one deferrable load. The system also includes a processor coupled in communication with the memory device. The processor is programmed to record a first operational measurement of the distribution transformer that is configured to transmit electric power to the at least one deferrable load. The processor is also programmed to record a second operational measurement of the at least one deferrable load. The processor is further programmed to determine a priority of energization of the at least one deferrable load within a queue as a function of at least one of the first operational measurement and the second operational measurement.

In another aspect, a method of assembling a distribution transformer deferrable load enhancement (DTDLE) system is provided. The method includes providing a distribution transformer and coupling the distribution transformer to at least one deferrable load positioned on at least one customer premises. The method also includes coupling a computing device that includes a processor and memory device coupled to the processor to the distribution transformer and the at least one customer premises. The method further includes configuring the computing device to record a first operational measurement of the distribution transformer that is configured to transmit electric power to the at least one deferrable load. The method also includes configuring the computing device to record a second operational measurement of the at least one deferrable load. The method further includes configuring the computing device to determine a priority of energization of the at least one deferrable load within a queue as a function of at least one of the first operational measurement and the second operational measurement.

In yet another aspect, an electric power distribution system is provided. The electric power distribution system includes at least one distribution transformer coupled to at least one deferrable load positioned on at least one customer premises. The system also includes a memory device configured to store a plurality of operational measurements of the at least one distribution transformer and the at least one deferrable load. The system further includes a processor coupled in communication with the memory device. The processor is programmed to record a first operational measurement of the at least one distribution transformer that is configured to transmit electric power to the at least one deferrable load. The processor is also programmed to record a second operational measurement of the at least one deferrable load. The processor is further programmed to determine a priority of energization of the at least one deferrable load within a queue as a function of at least one of the first operational measurement and the second operational measurement.

### BRIEF DESCRIPTION OF THE DRAWINGS

FIG. 1 is a simplified schematic diagram of a typical distribution system of an electric power grid;

FIG. 2 is a block diagram of an exemplary configuration of a distribution transformer deferrable load enhancement (DTDLE) system that may be used with the distribution system shown in FIG. 1;

FIG. 3 is a block diagram of an exemplary vehicle charging system that may be used with the DTDLE system shown in FIG. 2;

FIG. 4 is a graphical view of typical residential and commercial loads on a distribution transformer that may be observed with the DTDLE system shown in FIG. 2;

FIG. 5 is a graphical view of a typical expected loss of useful life of a distribution transformer that may be observed with overloads;

FIG. 6 is a tabular view of a pricing associated with a percentage of transformer overloading as shown in FIG. 5;

FIG. 7 is a flowchart of a method of scheduling a deferrable load to receive electric power from the distribution system shown in FIG. 1 using the DTDLE system shown in FIGS. 1 and 2;

FIG. 8 is a continuation of the flowchart shown in FIG. 7;

FIG. 9 is a graphical view of a distribution transformer loading that may be used to represent the method shown in FIGS. 7 and 8 when P_{AVAIL} is greater than 0%; and

FIG. 10 is a flowchart of an exemplary method of assembling the DTDLE system shown in FIG. 2.

### DETAILED DESCRIPTION OF THE INVENTION

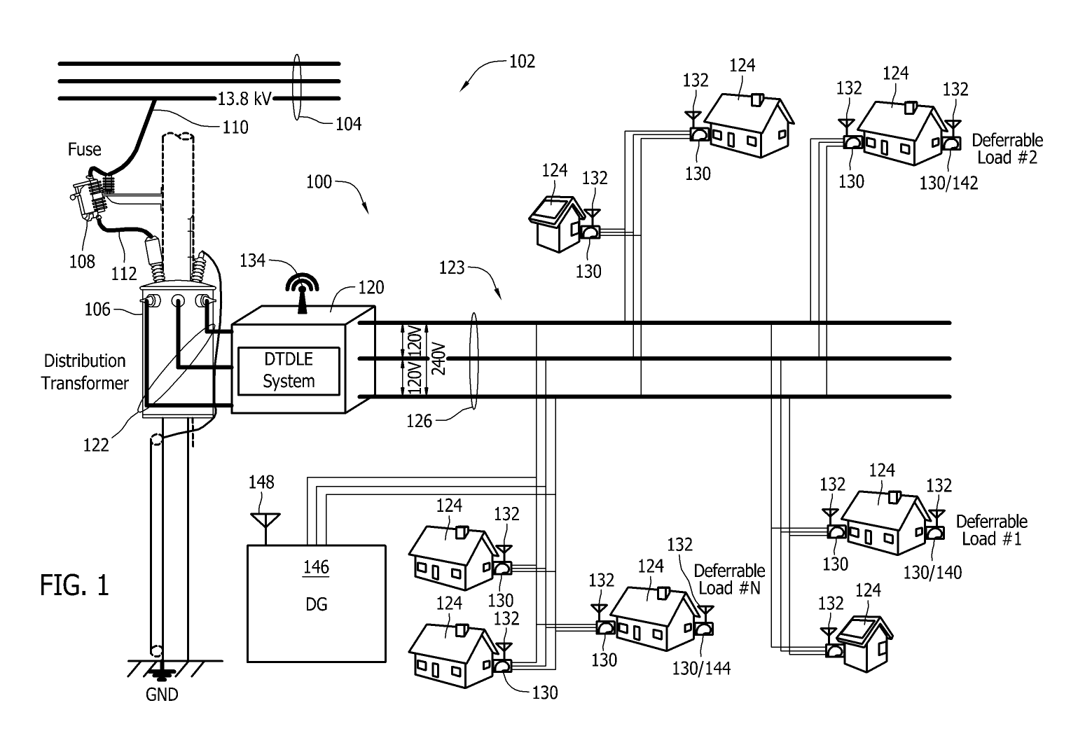

FIG. 1 is a simplified schematic diagram of a typical distribution system 100 of an electric power grid 102. In the exemplary embodiment, distribution system 100 includes three-phase (3Φ) 13.8 kilovolt (kV) distribution cables 104. Alternatively, cables 104 have any voltage that enables operation of distribution system 100 as described herein. Distribution system 100 also includes a distribution transformer 106 coupled to one of cables 104 via a fuse 108 and electrical conduits 110 and 112 upstream and downstream of fuse 108, respectively. In the exemplary embodiment, distribution transformer 106 is a pole-mounted transformer. Alternatively, distribution transformer 106 and associated components may be a pad-mounted transformer, integrated within a substation, or any other type of distribution transformer that enables operation of distribution system 100 as described herein. Moreover, distribution transformer 106 is a single-phase (1Φ) step-down transformer that is powered from distribution cables 104 with a voltage potential of approximately 13.8 kV (line-to-line) and steps-down the voltage to approximately 240 V line-to-line and 120 V line-to-neutral. Alternatively, distribution transformer is a three-phase (3Φ) transformer. Typically, distribution transformer 106 may have a load range between approximately 5 kilovolt-ampere (kVA) and approximately 500 kVA. In the exemplary embodiment, distribution transformer 106 has a load capacity between 25 kVA and 50 kVA, i.e., sufficient power transmission capability to supply power to approximately seven to ten residential locations.

Also, in the exemplary embodiment, distribution system 100 includes a distribution transformer deferrable load enhancement (DTDLE) system 120. DTDLE system 120 is coupled to distribution transformer 106 via a plurality of low-voltage cables 122. DTDLE system 120 is an intelligent distributed control device that is located on the low side, or downstream of distribution transformer 106. DTDLE system 120 facilitates automated scheduling of deferrable loads on distribution transformer 106 such that a potential for overloading transformer 106 is significantly reduced. As such, DTDLE system 120 facilitates reducing a potential of overloading distribution transformer 106, which in turn increases the associated useful life, reduces maintenance costs, and improves reliability.

In addition, DTDLE system 120 facilitates processing customer data by the associated owner/operator of distribution system 100 closer to the end user. DTDLE system 120 also facilitates making automated decisions locally based on such data, rather than collecting such data, transmitting that data to the back office, analyzing the data, and making decisions remotely based on the remote analysis. As such, DTDLE system 120 facilitates implementation of real time, localized management of a portion 123 of distribution system 100 downstream of DTDLE system 120, thereby operating as a micro-grid controller.

Further, in the exemplary embodiment, DTDLE system 120 is coupled to a plurality of customer residences 124 via portion 123 of distribution system 100. Portion 123 includes three lines 126 energized to approximately 240 V line-to-line and 120 V line-to-neutral. Each customer residence 124 includes a vehicle charging system 130 for charging, or providing electricity to, an electrically powered vehicle (EV) (not shown in FIG. 1). Each vehicle charging system 130 includes a transceiver 132 coupled in two-way communication with a transceiver 134 associated with DTDLE system 120. Moreover, each residence 124 includes sufficient hardware, software, and firmware to facilitate two-way communication between the customers in each residence 124 and DTDLE system 120, including, without limitation, a touch screen that displays charging options to each customer, receives a selection from the customer, transmits the selection to DTDLE system 120, and receives an acknowledgment by DTDLE system 120. Such charging options include, without limitation, increased rates associated with overloading transformer 106, as described further below. DTDLE system 120 uses any wireless standard that enables operation of DTDLE system 120 as described herein.

At least some vehicle charging systems 130 are deferrable loads, i.e., a first deferrable load 140, a second deferrable load 142, and an N^{th} deferrable load 144.

As used herein, the term “deferrable loads” refers to those residential and/or industrial loads that have an electric power draw that may be deferred until a later time. Such deferrable loads may include EV chargers, as well as other large loads that have a potential for overloading a distribution transformer as described herein, for example, without limitation, electric ovens and large air-conditioning systems. Moreover, each of such deferrable loads is uniquely identified by any method that facilitates operation of distribution system 100 and DTDLE system 120 as described herein. Also, as used herein, the term “deferrable load status” refers to one of two discrete statuses of the deferrable load. The first status is the deferrable load is not coupled to the distribution transformer and is not drawing any power therefrom, i.e., “OFF”. The second status is the deferrable load is coupled to the distribution transformer and is drawing at least some electric power therefrom, i.e., “ON”. Further, as used herein, the term “operational mode” refers to designating each of the deferrable loads as having one of two electric power draw modes. The first operational mode is a variable power draw mode, wherein the deferrable load draws varying values of electric power from the distribution transformer between 0% and 100% of rated capacity. The second operational mode is a rated power draw mode, wherein the deferrable load only draws electric power at its rated capacity.

Distribution system 100 may also include distributed generation device(s) 146 that is/are coupled to lines 126 of portion 123, and include a transceiver 148. Distribution system 100 includes any number of, and any type of, distributed generation devices 146, including, without limitation, diesel generators, micro-turbines, and solar collector arrays.

Distribution system 100 is shown with an exemplary number of customer residences 124. Alternatively, distribution system 100 has any number of customer residences 124 that enables operation of distribution system 100 as described herein.

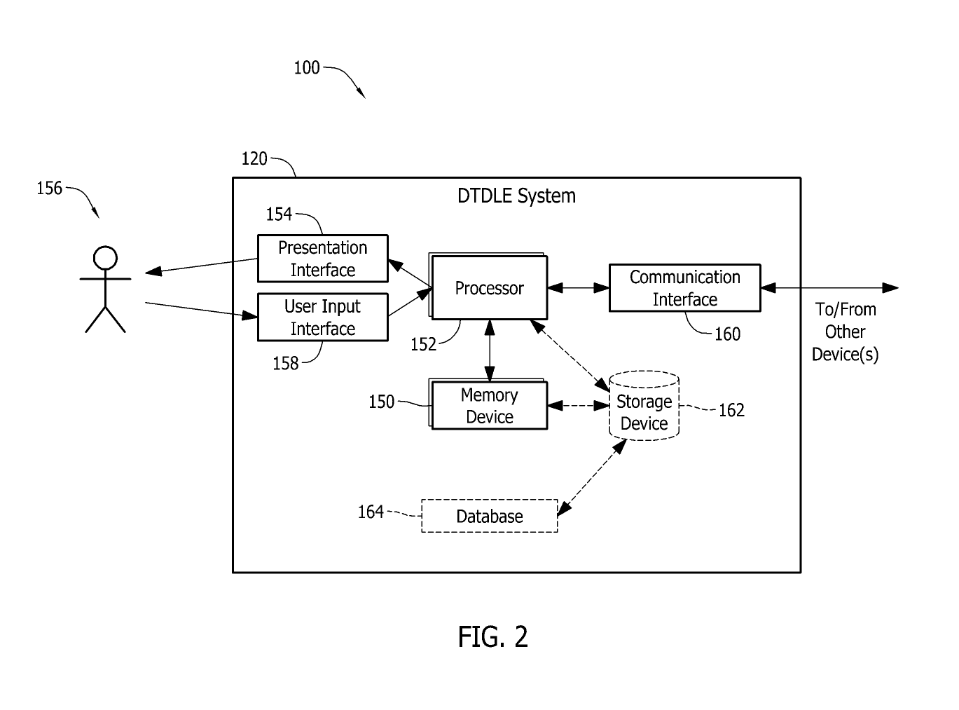

FIG. 2 is a block diagram of an exemplary configuration of distribution transformer deferrable load enhancement (DTDLE) system 120 that may be used with distribution system 100. Alternatively, any computer architecture that enables operation of DTDLE system 120 as described herein is used. In the exemplary embodiment, DTDLE system 120 facilitates collecting, storing, analyzing, displaying, and transmitting data associated with operation of distribution transformer 106 (shown in FIG. 1) in a distribution system 100 of electric power grid 102 (shown in FIG. 1). Also, in the exemplary embodiment, DTDLE system 120 facilitates load management of distribution system 100 downstream of distribution transformer 106, thereby managing load on transformer 106.

DTDLE system 120 includes a memory device 150 and a processor 152 operatively coupled to memory device 150 for executing instructions. In some embodiments, executable instructions are stored in memory device 150. DTDLE system 120 is configurable to perform one or more operations described herein by programming processor 152. For example, processor 152 may be programmed by encoding an operation as one or more executable instructions and providing the executable instructions in memory device 150. Processor 152 may include one or more processing units (e.g., in a multi-core configuration).

In the exemplary embodiment, memory device 150 is one or more devices that enable storage and retrieval of information such as executable instructions and/or other data. Memory device 150 may include one or more computer readable media, such as, without limitation, dynamic random access memory (DRAM), static random access memory (SRAM), a solid state disk, and/or a hard disk.

Memory device 150 may be configured to store a variety of operational data transmitted from sensing devices (not shown) associated with distribution transformer 106 including, without limitation, values of electric power transmitted through the transformers, sometimes referred to as transformer loading. Some embodiments of memory device 150 also include, without limitation, operational data associated with ambient temperatures in the vicinity of each of the transformers, transformer oil temperatures, and transformer winding temperatures. Moreover, in the exemplary embodiment, operational data associated with deferrable loads coupled to distribution transformer 106 is stored within memory device 150, such data including, without limitation, deferrable load status, present real power draw, previous maximum real power draws, and an operational mode of the deferrable load.

In some embodiments, DTDLE system 120 includes a presentation interface 154 coupled to processor 152. Presentation interface 154 presents information, such as a user interface and/or an alarm, to a user 156. For example, presentation interface 154 may include a display adapter (not shown) that may be coupled to a display device (not shown), such as a cathode ray tube (CRT), a liquid crystal display (LCD), an organic LED (OLED) display, and/or a hand-held device with a display. In some embodiments, presentation interface 154 includes one or more display devices. In addition, or alternatively, presentation interface 154 may include an audio output device (not shown) (e.g., an audio adapter and/or a speaker).

In some embodiments, DTDLE system 120 includes a user input interface 158. In the exemplary embodiment, user input interface 158 is coupled to processor 152 and receives input from user 156. User input interface 158 may include, for example, a keyboard, a pointing device, a mouse, a stylus, and/or a touch sensitive panel (e.g., a touch pad or a touch screen). A single component, such as a touch screen, may function as both a display device of presentation interface 154 and user input interface 158.

A communication interface 160 is coupled to processor 152 and is configured to be coupled in communication with one or more other devices, such as vehicle charging systems 130 (shown in FIG. 1), distributed generation device 146 (shown in FIG. 1), another DTDLE system 120, and any device capable of accessing DTDLE system 120 including, without limitation, a portable laptop computer, a personal digital assistant (PDA), and a smart phone. Communication interface 160 may include, without limitation, a wired network adapter, a wireless network adapter, a mobile telecommunications adapter, a serial communication adapter, and/or a parallel communication adapter. Communication interface 160 may receive data from and/or transmit data to one or more remote devices. For example, a communication interface 160 of one DTDLE system 120 may transmit transaction information to communication interface 160 of another DTDLE system 120. DTDLE system 120 may be web-enabled for remote communications, for example, with a remote desktop computer (not shown).

Presentation interface 154 and/or communication interface 160 are both capable of providing information suitable for use with the methods described herein (e.g., to user 126 or another device). Accordingly, presentation interface 154 and communication interface 160 may be referred to as output devices. Similarly, user input interface 158 and communication interface 160 are capable of receiving information suitable for use with the methods described herein and may be referred to as input devices.

Processor 152 and/or memory device 120 may also be operatively coupled to a storage device 162. Storage device 162 is any computer-operated hardware suitable for storing and/or retrieving data, such as, but not limited to, data associated with a database 164. In the exemplary embodiment, storage device 162 is integrated in DTDLE system 120. For example, DTDLE system 120 may include one or more hard disk drives as storage device 162. Moreover, for example, storage device 162 may include multiple storage units such as hard disks and/or solid state disks in a redundant array of inexpensive disks (RAID) configuration. Storage device 162 may include a storage area network (SAN) and/or a network attached storage (NAS) system. Alternatively, storage device 162 is external to DTDLE system 120 and may be accessed by a storage interface (not shown).

Also, in the exemplary embodiment, database 164 contains a variety of operational data associated with distribution transformer 106 including, without limitation, values of electric power transmitted through transformer 106, sometimes referred to as transformer loading. Some embodiments of database 164 also include, without limitation, operational data associated with ambient temperatures in the vicinity of each of transformer 106, transformer oil temperatures, and transformer winding temperatures. All of the collected data is associated with, or tagged, with a time and date of measurement.

Moreover, in the exemplary embodiment, operational data associated with deferrable loads 140 through 144 coupled to distribution transformer 106 is maintained within database 164, such data including, without limitation, deferrable load status, values of present real power draw, previous high values of real power draws, and an operational mode of deferrable loads 140 through 144. All of the collected data is associated, or tagged with, with a time and date of measurement.

The embodiments illustrated and described herein as well as embodiments not specifically described herein but within the scope of aspects of the disclosure, constitute exemplary means for recording, storing, retrieving, and displaying operational data associated with a distribution transformer. For example, DTDLE system 120, and any other similar computer device added thereto or included within, when integrated together, include sufficient computer-readable storage media that is/are programmed with sufficient computer-executable instructions to execute processes and techniques with a processor as described herein. Specifically, DTDLE system 120 and any other similar computer device added thereto or included within, when integrated together, constitute an exemplary means for recording, storing, retrieving, and displaying operational data associated with a distribution transformer.

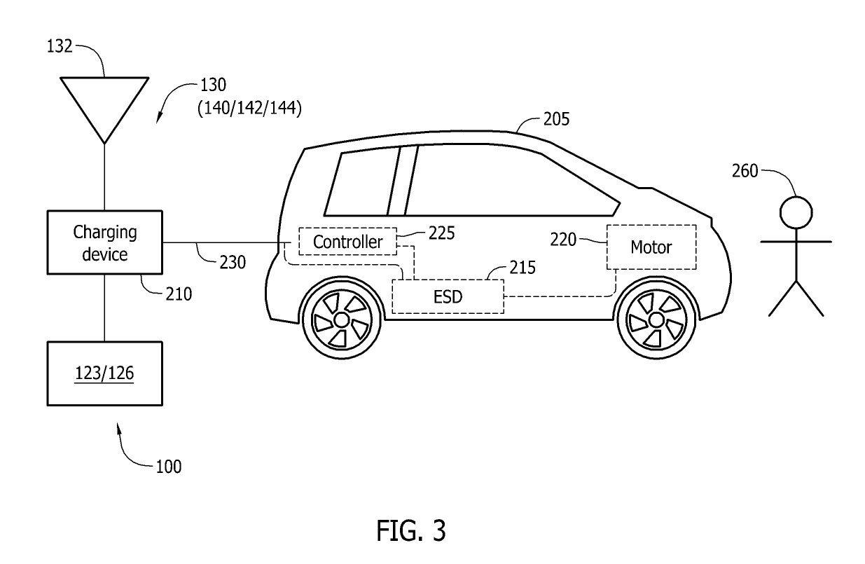

FIG. 3 is a block diagram of exemplary vehicle charging system 130 for use with DTDLE system 120 (shown in FIGS. 1 and 2). Vehicle charging system 130 charges, or provides electricity to, an electrically powered vehicle (EV) 205. Also, vehicle charging system 130 may, or may not, be a deferrable load 140, 142, or 144. In the exemplary embodiment, vehicle charging system 130 includes a charging device 210 that may be coupled to EV 205. Also, in the exemplary embodiment, EV 205 includes at least one energy storage device 215, such as a battery and/or a capacitor, coupled to a motor 220. Furthermore, EV 205 includes a vehicle controller 225 coupled to energy storage device 215.

Further, in the exemplary embodiment, charging device 210 is removably coupled to energy storage device 215 and to vehicle controller 225 via at least one power conduit 230. Alternatively, charging device 210 may be coupled to energy storage device 215 and/or vehicle controller 225 via any other conduit or conduits, and/or charging device 210 may be coupled to vehicle controller 225 via a wireless data link (not shown). Power conduit 230 includes at least one conductor (not shown) for supplying electricity to energy storage device 215 and/or to any other component within EV 205, and at least one conductor (not shown) for transmitting data to and receiving data from vehicle controller 225 and/or any other component within EV 205. Alternatively, power conduit 230 may include a single conductor that transmits and/or receives power and/or data, or any other number of conductors that enables vehicle charging system 130 to function as described herein. Moreover, in the exemplary embodiment, charging device 210 is coupled to an electric power source, such as distribution system 100, and more specifically, lines 226 of portion 123 of distribution system 100.

Vehicle charging system 130 is coupled in communication with DTDLE system 120 via transceiver 132. Operational data associated with vehicle charging system 130 includes, without limitation, vehicle charging system status, present real power draw, previous maximum real power draws, and an operational mode of vehicle charging system 130.

During operation, in the exemplary embodiment, a user 260 couples energy storage device 215 to charging device 210 with power conduit 230. User 260 may interact with charging device 210 by accessing a user interface (not shown) of charging device 210 to enter information, such as payment information, and/or to initiate power delivery to energy storage device 215. Once user 260 is authenticated, charging device 210 receives power from lines 226 of portion 123 of distribution system 100 and provides the power to energy storage device 215 through power conduit 230. When energy storage device 215 has been charged to a desired level, charging device 210 ceases delivering power to energy storage device 215, and user 260 disengages power conduit 230 from energy storage device 215.

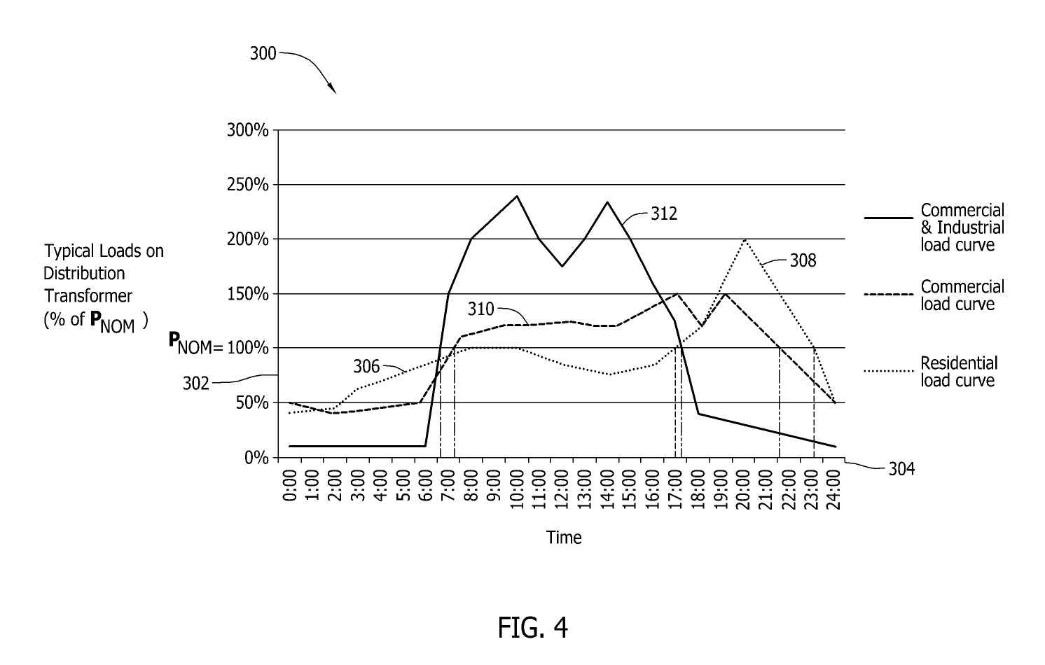

FIG. 4 is a graphical view 300 of typical loading on distribution transformer 106 (shown in FIG. 1) that may be observed with DTDLE system 120 (shown in FIG. 2). In general, distribution transformers have certain load curves that depend on the type of customer, time of the day, day of the week, and outside temperature.

Graphical view 300 includes a y-axis 302 extending from 0% to 300% in increments of 50%, wherein the percentage values are based on the nominal, or rated nameplate load for distribution transformer 106 (shown in FIG. 1), such nameplate load rating hereon referred to as P_{NOM} and referenced to the value of 100% of rated nameplate load, that is usually measured in units of kilovolt-amperes (kVA). Values above 100% represent overloading of distribution transformer 106. Graphical view 300 also includes an x-axis 304 representative of time along a 24-hour clock from 0:00 to 24:00 in increments of 1 hour. Graphical view 300 further includes a first curve 306 representative of typical residential load on distribution transformer 106 over a typical 24-hour period. First curve 306 exceeds P_{NOM} between approximately 17:00 and 23:00, drops below P_{NOM} at approximately 23:00, and has a peak 308 between 19:00 and 21:00 indicative of loads being energized including, without limitation, residential appliances (not shown) and vehicle charging systems 130 (shown in FIGS. 2 and 3). Therefore, residential loads in distribution system 100 (shown in FIG. 1) overload distribution transformer 106 to a value of approximately 200% of P_{NOM} for at least a portion of a time period between approximately 17:00 and 23:00.

Graphical view 300 also includes a second curve 310 representative of typical commercial load on distribution transformer 106 over a typical 24-hour period. Second curve 310 exceeds P_{NOM} between approximately 7:00 to 22:00 indicative of loads being energized including, without limitation, commercial appliances (not shown) and commercial vehicle charging systems (not shown). In many embodiments, commercial establishments using electric power supplied via distribution system 100 and intermingled with customer residences 124 include small shops and businesses.

Graphical view 300 also includes a third curve 312 representative of typical commercial and industrial loads on distribution transformer 106 over a typical 24-hour period. In some embodiments, distribution system 100 serves commercially-zoned regions, wherein there are few, if any, residential loads. Third curve 312 exceeds P_{NOM} between approximately 6:00 to 18:00 indicative of loads being energized including, without limitation, commercial and/or industrial appliances (not shown) and commercial and/or industrial vehicle charging systems (not shown). Therefore, commercial and/or industrial loads in distribution system 100 overload distribution transformer 106 between approximately 6:00 and 18:00.

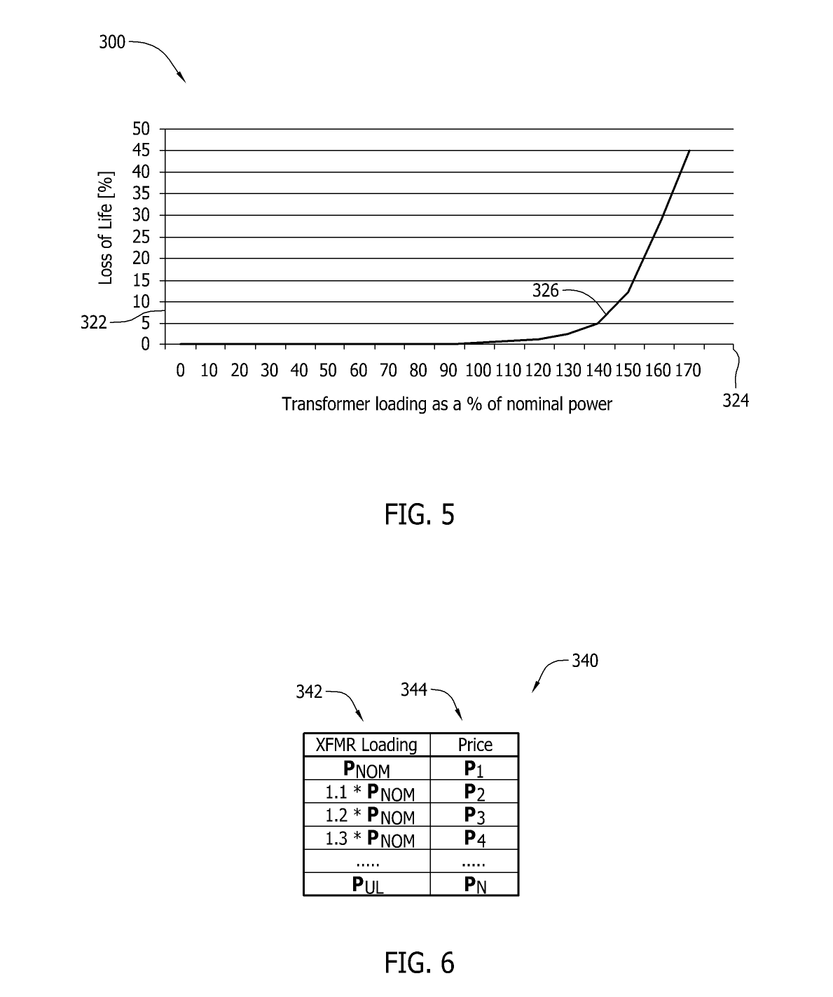

FIG. 5 is a graphical view 320 of a typical expected loss of useful life of distribution transformer 106 (shown in FIG. 1) that may be observed with overloads of transformer 106. In general, most utilities and transformer manufacturers have gathered sufficient empirical data over the life spans of numerous makes and models of distribution transformers to generate expected useful life spans for various loading schemes. Such empirical data facilitates deriving curves that predict a decrease in useful life span of distribution transformers for a given level of overloading.

Graphical view 320 includes a y-axis 322 representing a decrease in the useful lifespan of transformer 106 that extends from 0% to 50% in increments of 5%, wherein the percentage values are based on a nominal useful life span of distribution transformer 106 of 100%. Graphical view 320 also includes an x-axis 324 representative of a percentage of load on distribution transformer 106 from 0% to 170% of P_{NOM} for distribution transformer 106 in increments of 10%.

Graphical view 300 also includes a curve 316 representative of a typical decrease in useful life of transformer 106 as a function of a percentage of loading of transformer 106 with respect to P_{NOM}. For example, from 0% to 100% of P_{NOM} for distribution transformer 106, a 0% decrease in useful life of transformer 106 may be expected. Also, exceeding 100% of P_{NOM} increases a loss of life, i.e., decreases the useful life span of transformer 106 on an increasing basis as the percentage of overloading of transformer 106 increases. In the exemplary embodiment, graphical view 320 assumes that a decrease in useful life is associated with a consistent value of overloading for the life of transformer 106. In general, and as shown in FIG. 4, transformer 106 may be overloaded for only a portion of a 24 hour period. However, sufficient empirical data exists to determine similar curves for periodic overloading. Therefore, costs of transformer overloading may be determined as a function of a value of overloading and an integrated value of the time period of overloading.

FIG. 6 is a tabular view, or table 340 of a pricing structure associated with a percentage of overloading of distribution transformer 106 (shown in FIG. 1). Table 340 has a first column 342 that includes values of loading of transformer 106 as a multiple of P_{NOM} of transformer 106. Second column 344 includes values of pricing P₁ through Pₙ that are associated with a value of overloading in column 342. The values of pricing in column 344 represent the cost to a utility's customers for such customers electing to load transformer 106 such that it is overloaded, thereby compensating the utility for the decreased useful lifespan of transformer 106 and the accelerated maintenance, repair, and/or replacement.

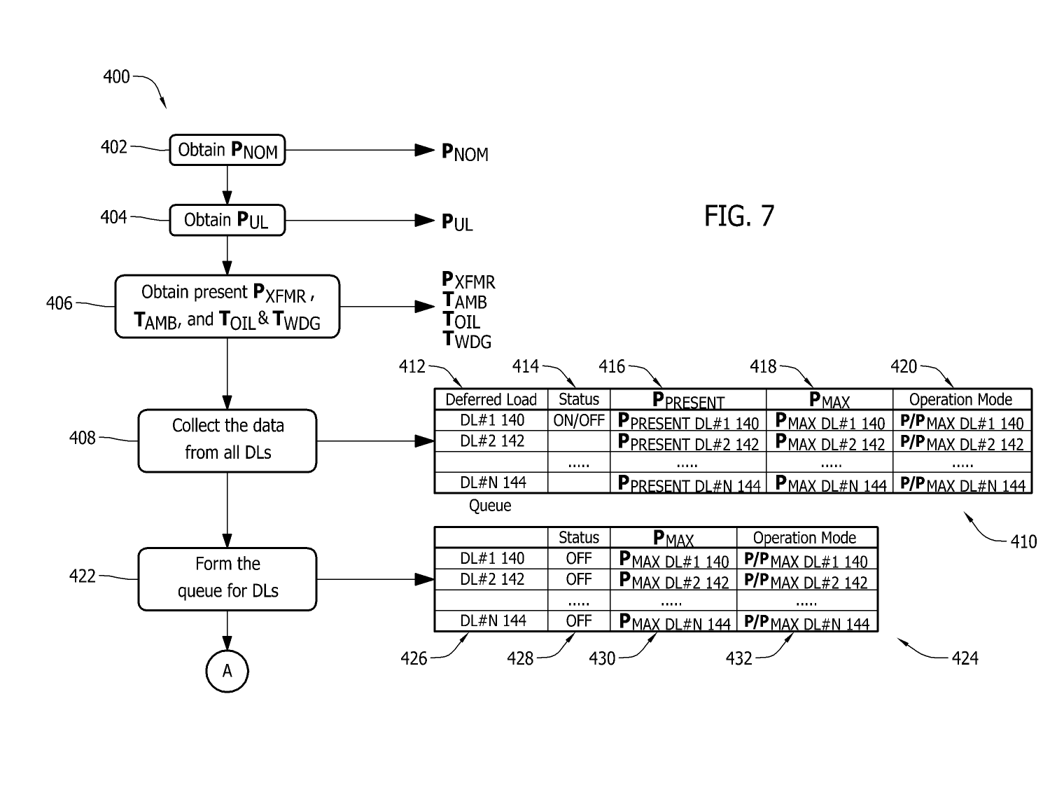

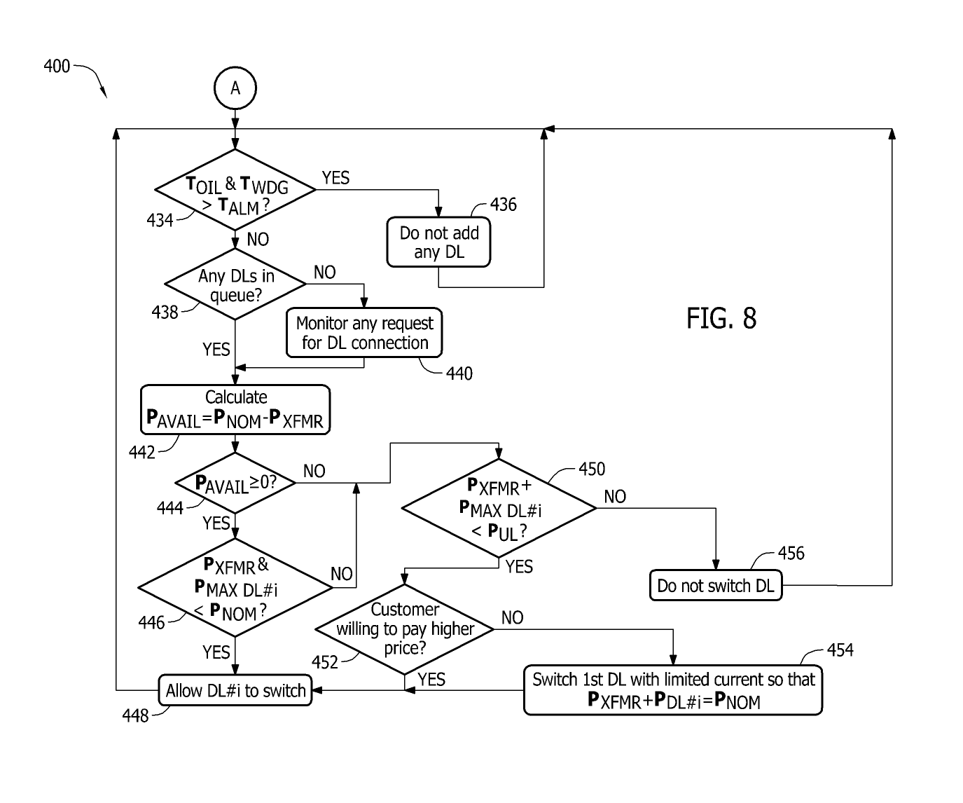

FIG. 7 is a flowchart of a method 400 of scheduling deferrable loads 140, 142, and/or 144 (all shown in FIG. 1) to receive electric power from distribution system (100) shown in FIG. 1 using DTDLE system 120 (shown in FIGS. 1 and 2). FIG. 8 is a continuation of the flowchart shown in FIG. 7. In the exemplary embodiment, all deferrable loads (DLs) 140, 142, and 144 are registered with the utility and at least one associated data record (not shown) is resident within database 164 (shown in FIG. 2) for each of DLs 140, 142, and 144.

In the exemplary embodiment, method 400 includes obtaining 402 the value of P_{NOM} for distribution transformer 106 (shown in FIG. 1) and stored within database 164 (shown in FIG. 2). The value for the overload capability, or upper limit (referred to hereon as P_{UL}) of distribution transformer 106 is also obtained 404 and stored within database 164. The P_{UL} of distribution transformer 106 may be obtained from at least one of, or a combination of, the utility, and the transformer manufacturer. Alternatively, the P_{UL} of distribution transformer 106 may be obtained from data based on a “hot spot” temperature of transformer 106. In addition, the value for P_{UL}, measured in units of kilowatts (kW), and referenced herein as a percentage value of P_{NOM}, may be adjusted upward or downward at the discretion of the utility based on parameters that may include, without limitation, the amount of overloading that the utility is willing to accept. The present values of loading of transformer 106 (referred to hereon as P_{XFMR}) are recorded 406 and stored in database 164. Also, temperatures that include, without limitation, ambient temperatures (T_{AMB}), transformer oil temperatures (T_{OIL}), and transformer winding temperatures (T_{WDG}) may optionally be recorded and stored within database 164.

Data is collected 408 from all DLs 140 through 144 positioned within distribution system 100 and stored within database 164. Such data includes, without limitation, a status of each DL 140 through 144, present real power draw for each DL 140 through 144, previous maximum real power draws for each DL 140 through 144, and an operational mode for each DL 140 through 144. Such data may be represented in a table 410. A first column 412 of table 410 includes DLs #1 (140) through #N (144), wherein DL #i represents any of DLs #1 (140) through #N (144) that are in queue 424. A second column 414 of table 410 includes the status of each DL in column 412, wherein the status is either a discrete “OFF” or “ON”. As described above, and as used herein, the term “deferrable load status” refers to one of two discrete statuses of the deferrable load. The first status is the deferrable load is not coupled to the distribution transformer and is not drawing any power therefrom, i.e., the “OFF” status. The second status is the deferrable load is coupled to the distribution transformer and is drawing at least some electric power therefrom, i.e., the “ON” status.

A third column 416 of table 410 includes the present values of load, i.e., P_{CURRENT}, transmitted to each of DLs #1 (140) through #N (144) in units of kW. A fourth column 418 of table 410 includes the maximum values of deferred load, i.e., P_{MAX}. A fifth column 420 of table 410 includes a calculated ratio of the contents of third column 416 to the contents of fourth column 418, i.e., P_{CURRENT}/P_{MAX} for each of DLs #1 (140) through #N (144) to determine the immediate proximity of actual load to the maximum load for the associated DL. The values for entries in fifth column 420 may vary between 0% and 100% of the associated P_{MAX}. Therefore, calculating the ratios facilitates determining if the associated DLs typically run close to the maximum load, or, alternatively, operate at a variable load.

Also, in the exemplary embodiment, method 400 includes populating 422 a queue 424 with DLs as the DLs are attempted to be energized to receive electric power from distribution system 100. Queue 424 includes a first column 426 that includes each of DLs #1 (140) through #N (144). First column 426 of queue 424 is populated as the associated request for energization is received. Such operation is contrasted to those loads that are immediately energized when requested, e.g., when a light switch is operated. As long as sufficient capacity within the parameters programmed into DTDLE system 120 is available, queue 424 will remain unpopulated. Queue 424 will begin to populate when there is not sufficient capacity within the parameters programmed into DTDLE system 120. Queue 424 also includes a second column 428 that includes the status of each DL in column 426, wherein the status is always a discrete “OFF” while DTDLE system 120 manages the timing of energization of the DLs in queue 424. Queue 424 further includes a third column 430 that is similar to fourth column 418 of table 410. Queue 424 also includes a fourth column 432 that is similar to fifth column 420 of table 410.

Referring to FIG. 8, once a DL request is made by a customer, DTDLE system 120 determines 434, for those embodiments that measure T_{OIL} and T_{WDG}, if the measured temperatures exceed an alarm setpoint (T_{ALM}) stored in database 164. If the measured temperatures exceed the setpoint, the DL is not added 436 to queue 424 (shown in FIG. 7). Otherwise, a determination 438 is made if there are any DLs in queue 424. If there are no DLs in queue 424, DTDLE system 120 continues to monitor 440 for any request for a DL connection.

If there are DLs in queue 424, DTDLE system 120 determines 442 the remaining loading capacity available (P_{AVAIL}) to load distribution transformer 106 without overloading transformer 106. DTDLE system 120 uses an expression such as P_{AVAIL}=P_{NOM}−P_{XFMR}. DTDLE system 120 determines 444 if P_{AVAIL} is greater than, or equal to, 0%. If P_{AVAIL} is greater than, or equal to, 0%, then DTDLE system 120 determines 446 if P_{XFMR}+P_{MAX DL#i} is less than P_{NOM}, wherein P_{MAX DL#i}, represents P_{MAX} for any of DLs #1 (140) through #N (144) that are in queue 424. If it is determined that P_{XMFR}+P_{MAX DL#i} is less than P_{NOM}, then DTDLE system 120 permits DL #i to change 448 its status from “OFF” to “ON” and permits DL #i to be removed from queue 424. Alternatively, if P_{AVAIL} is less than 0%, indicating that there is no further capacity on distribution transformer 106, or if P_{XMFR}+P_{MAX DL#i} is greater than P_{NOM}, then a determination 450 is made if P_{XFMR}+P_{MAX DL#i} less than P_{UL}.

If it is determined that P_{XFMR}+P_{MAX DL#i} is less than P_{UL}, then a determination 452 is made if the customer will be willing to pay a higher price (per FIG. 6) for energizing DL #i immediately, or alternatively, wait until loading on transformer 106 decreases sufficiently to permit energizing DL #i without overloading transformer 106. If the customer is willing to pay the higher price, then DTDLE system 120 permits DL #i to change 448 its status from “OFF” to “ON”, permits DL #i to be removed from queue 424, and permits overloading of transformer 106. If the customer is not willing to pay the higher price, then DL #i will be placed in queue 424.

Moreover, once DL #i is placed in queue 424, the utility may limit 454 the electric current transmitted to DL #i such that P_{XFMR}+P_{DL#i} equals P_{NOM} if DL #i can operate properly under P_{MAX DL#i} conditions. This electric current will be variable and will be adjusted as necessary so that the condition of P_{XFMR}+P_{DL#i} equals P_{NOM} is satisfied. If the condition cannot be satisfied, DL #i remains in queue 424. If it is determined that P_{XFMR}+P_{MAX DL#i} is not less than P_{UL}, then DL #i remains 456 in queue 424 until all of the conditions necessary to remove DL #i from queue 424 are satisfied.

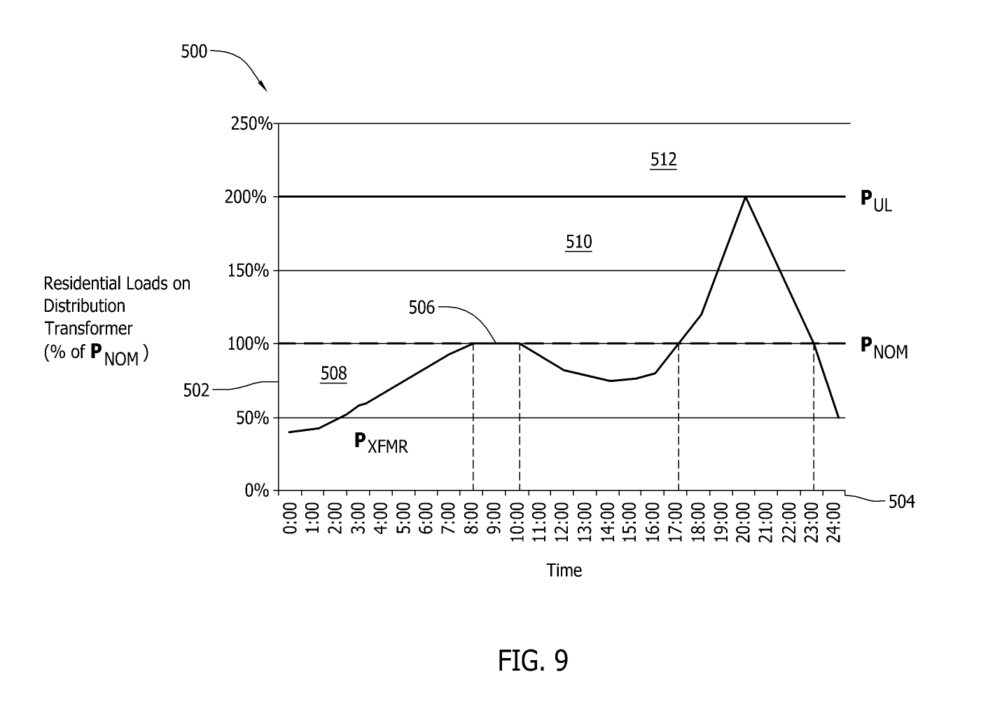

FIG. 9 is a graphical view 500 of a distribution transformer loading that may be used to represent method 400 (shown in FIGS. 7 and 8) when P_{AVAIL} is greater than 0%. In general, DTDLE system 120 (shown in FIGS. 1 and 2) controls the loading of distribution transformer 106 (shown in FIG. 1). As described above, P_{NOM} represents the transformer nameplate rated loading, while P_{UL} represents the upper limit on the transformer loading that the utility does not want to exceed.

Graphical view 500 includes a y-axis 502 extending from 0% to 250% in increments of 50%, wherein the percentage values are based on P_{NOM} that is usually measured in units of kVA. Values above 100% represent overloading of distribution transformer 106. Graphical view 500 also includes an x-axis 504 representative of time along a 24-hour clock from 0:00 to 24:00 in increments of 1 hour. Graphical view 500 further includes a curve 506 representative of a typical residential load on distribution transformer 106 over a typical 24-hour period, i.e., P_{XFMR}. Graphical view 500 also includes a first region 508 defined below P_{NOM}. Graphical view 500 further includes a second region 510 defined between P_{NOM} and P_{UL}. Graphical view 500 also includes a third region 512 defined above P_{UL}.

In the exemplary embodiment, between approximately 0:00 and approximately 17:00, P_{XFMR} is less than P_{NOM}, and the expression P_{AVAIL}=P_{NOM}−P_{XFMR} generates the result that P_{AVAIL} is greater than 0%. Therefore, P_{XFMR} curve 506 is at or below P_{NOM}, and a request to energize a deferrable load will likely be granted by DTDLE 120 as long as there is sufficient P_{AVAIL} such that adding the load will not result in P_{XFMR} curve 506 exceeding P_{NOM}.

Also, in the exemplary embodiment, after approximately 17:00, P_{XFMR} is greater than P_{NOM}, and the expression P_{AVAIL}=P_{NOM}−P_{XFMR} generates the result that P_{AVAIL} is less than 0%. For those situations, energizing a particular deferrable load may increase the load such that P_{XFMR} curve 506 will exceed P_{NOM}, and the customer will be requested to pay a higher price. If the customer agrees, as shown in the exemplary embodiment, DTDLE 120 will permit energization of that deferrable load. In that case, P_{XFMR} curve 506 will exceed P_{NOM}, distribution transformer 106 will be allowed to operate in region 510, and additional loads will be permitted as long as P_{XFMR} curve 506 does not exceed P_{UL}, wherein operation in third region 512 is not permitted. In addition, if the associated deferrable load can normally operate below P_{MAX} conditions, meaning that for proper operation the load does not require full rated current, DTDLE 120 may allow the deferrable load to switch the “ON” state, but it will regulate its output current. This decision will be based on the minimum current that the deferrable load requires for normal operation.

Alternatively, if the customer does not agree to the increased pricing, the deferrable load is not permitted to energize and is placed in queue 424 (shown in FIG. 8) until there is sufficient capacity to load transformer 106 with the deferrable load such that P_{XFMR} does not exceed P_{NOM} and that particular load is up next in queue 424.

DTDLE system 120 facilitates decreasing the System Average Interruption Frequency Index (SAIFI). SAIFI is the ratio of the total number of customer interruptions to the total number of customers served and is commonly used as a reliability indicator by electric power utilities, is often used to represent a value of the average number of interruptions that a customer would experience, and is measured in units of interruptions per customer. For example, one recent value of SAIFI in North America was approximately 1.10 interruptions per customer.

Furthermore, DTDLE system 120 facilitates decreasing the System Average Interruption Duration Index (SAIDI). SAIDI is the ratio of the sum of all customer interruption durations to the total number of customers served and is commonly used as another reliability indicator by electric power utilities, is often used to represent a value of the average outage duration for each customer served, and is measured in units of time, often minutes or hours. For example, one recent value of SAIDI in North America was approximately 1.50 hours.

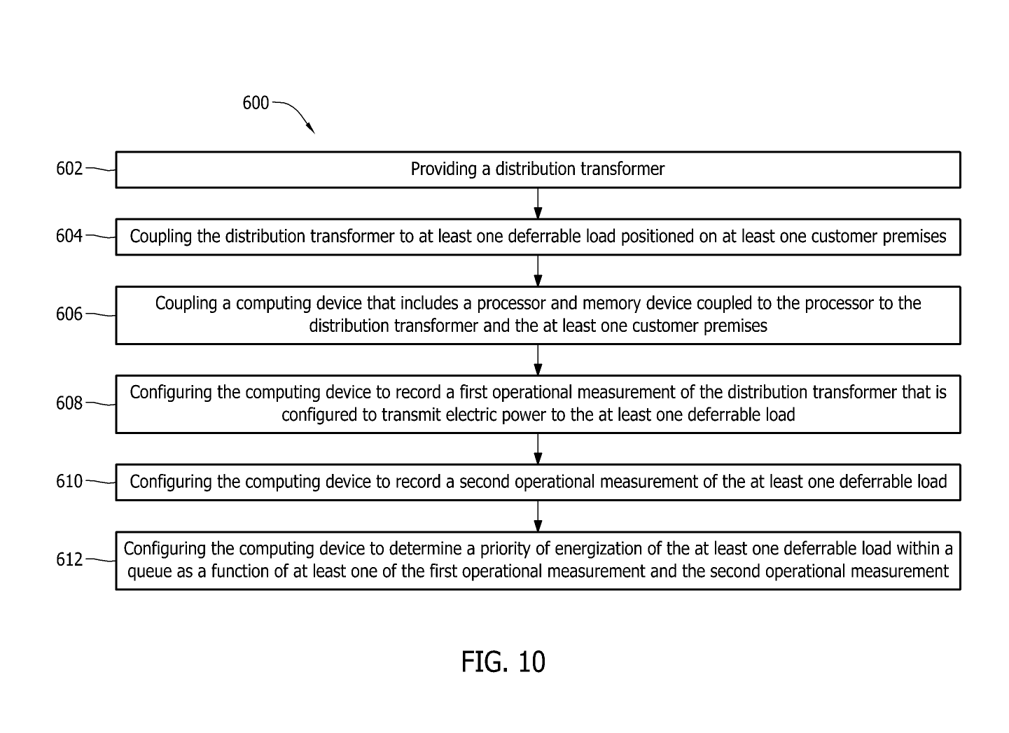

FIG. 10 is a flowchart an exemplary method 600 of assembling DTDLE system 120 (shown in FIGS. 1 and 2). In the exemplary embodiment, distribution transformer 106 (shown in FIG. 1) is provided 602. Distribution transformer 106 is coupled 604 to at least one deferrable load, e.g., DLs #1 (140) through #N (144) (all shown in FIG. 1) positioned on at least one customer premises 124 (shown in FIG. 1). Distribution transformer 106 is configured to transmit electric power to at least one of DLs #1 (140) through #N (144). A computing device, e.g., DTDLE system 120, that includes processor 152 and memory device 150 coupled to processor 152, is coupled 606 to distribution transformer 106 and at least one customer premises 124. DTDLE system 120 is configured 608 to record a first operational measurement of distribution transformer 106. DTDLE system 120 is also configured 610 to record a second operational measurement of at least one of DLs #1 (140) through #N (144). DTDLE system 120 is further configured 612 to determine a priority of energization of at least one of DLs #1 (140) through #N (144) within queue 424 (shown in FIG. 7) as a function of at least one of the first operational measurement and the second operational measurement.

In contrast to known electric power distribution systems, the methods, systems, and apparatus described herein provide improved management of distribution transformers installed therein. Specifically, in contrast to known electric power distribution systems, the methods, systems, and apparatus described herein enable an improved, or extended, useful life of distribution transformers. More specifically, in contrast to known electric power distribution systems, the methods, systems, and apparatus described herein enable operating localized portions of larger distribution systems to control loading of the transformer by queuing those deferrable loads that may increase the transformer loading above a nominal value. Also, in contrast to known electric power distribution systems, the methods, systems, and apparatus described herein enable energizing those deferrable loads on a scheduled basis. Such basis includes the order of receipt of the request to energize as it arrived in the queue, the expected value of current draw by each load as a function of the greatest known current draw by that particular deferrable load, and a willingness of the associated customer to pay an increased cost of energizing the load to offset the decrease in the expected life of the transformer. Therefore, in contrast to known electric power distribution systems, the methods, systems, and apparatus described herein enable increasing reliability and decreasing outages (SAIFI and SAIDI), and decreasing maintenance costs of distribution transformers. Also, therefore, the costs of the decreased transformer useful life are borne by those customers directly associated with the decreased life, and those customers that elect to not pay more are spared unplanned outages.

Further, in contrast to known electric power distribution systems, the methods, systems, and apparatus described herein enable localized and automated management of distribution transformers such that the granularity of such management is increased, thereby enabling greater control of the deferrable loads and the transformer. Moreover, in contrast to known electric power distribution systems, the methods, systems, and apparatus described herein enable reducing the volume of communications and data traffic transmitted through the channels between the localized portions of the distribution system and an associated utility's back office, thereby enabling a reduction in the size of the associated databases and bandwidth of the associated data channels. Such localized data management as enabled by the methods, systems, and apparatus described herein reduces operational latencies associated with remote decision-making and operation of localized devices.

An exemplary technical effect of the methods, systems, and apparatus described herein includes at least one of (a) using localized data collection and management to schedule deferrable loads to reduce the potential of exceeding the nominal nameplate power rating of a distribution transformer; (b) using the localized management and control of the distribution transformers to store requests to energize deferrable loads in a queue; (c) permitting those queued loads to energize on a scheduled basis that is based on the order of receipt of the request to energize as it arrived in the queue, the expected value of current draw by each load as a function of the greatest known current draw by that particular deferrable load, and a willingness of the associated customer to pay an increased cost of energizing the load to offset the decrease in the expected life of the transformer; (d) allowing limited overloading of the distribution transformer, while not permitting exceeding an upper limit of the transformer load as determined by the utility; and, (e) decreasing time latencies associated with managing the loading of local distribution transformers.

The methods and systems described herein are not limited to the specific embodiments described herein. For example, components of each system and/or steps of each method may be used and/or practiced independently and separately from other components and/or steps described herein. In addition, each component and/or step may also be used and/or practiced with other assemblies and methods.

This written description uses examples to disclose the invention, including the best mode, and also to enable any person skilled in the art to practice the invention, including making and using any devices or systems and performing any incorporated methods. The patentable scope of the invention is defined by the claims, and may include other examples that occur to those skilled in the art. Such other examples are intended to be within the scope of the claims if they have structural elements that do not differ from the literal language of the claims, or if they include equivalent structural elements with insubstantial differences from the literal languages of the claims.

Some embodiments involve the use of one or more electronic or computing devices. Such devices typically include a processor or controller, such as a general purpose central processing unit (CPU), a graphics processing unit (GPU), a microcontroller, a reduced instruction set computer (RISC) processor, an application specific integrated circuit (ASIC), a programmable logic circuit (PLC), and/or any other circuit or processor capable of executing the functions described herein. The methods described herein may be encoded as executable instructions embodied in a computer readable medium, including, without limitation, a storage device and/or a memory device. Such instructions, when executed by a processor, cause the processor to perform at least a portion of the methods described herein. The above examples are exemplary only, and thus are not intended to limit in any way the definition and/or meaning of the term processor.

While the invention has been described in terms of various specific embodiments, those skilled in the art will recognize that the invention can be practiced with modification within the spirit and scope of the claims.

What is claimed is:

1. A system for enhancing deferrable load management of a distribution transformer, said system comprising:
a memory device configured to store a plurality of operational measurements of a distribution transformer and at least one deferrable load; and
a processor coupled in communication with said memory device, said processor programmed to:
record a first operational measurement of the distribution transformer that is configured to transmit electric power to the at least one deferrable load;
record a second operational measurement of the at least one deferrable load; and
determine a priority of energization of the at least one deferrable load within a queue as a function of at least one of the first operational measurement and the second operational measurement.

2. A system in accordance with claim 1, wherein the first operational measurement of the distribution transformer comprises at least one of:
a value of electric power transmitted through the distribution transformer;
an ambient temperature value;
an oil temperature value of the distribution transformer; and
a winding temperature value of the distribution transformer.

3. A system in accordance with claim 1, wherein the second operational measurement of the at least one deferrable load comprises at least one of:
a status of the at least one deferrable load;
a value of present real electric power draw;
a previous high value of real electric power draw; and
an operational mode of the at least one deferrable load.

4. A system in accordance with claim 3, wherein said status of the at least one deferrable load comprises at least one of:
a first status, wherein the deferrable load is not coupled to the distribution transformer and is not drawing electric power therefrom; and
a second status, wherein the deferrable load is coupled to the distribution transformer and is drawing at least some electric power therefrom.

5. A system in accordance with claim 3, wherein said operational mode of the at least one deferrable load comprises at least one of:
a first operational mode, wherein the at least one deferrable load draws varying values of electric power from the distribution transformer; and
a second operational mode, wherein the at least one deferrable load only draws electric power at its rated capacity from the distribution transformer.

6. A system in accordance with claim 1, wherein said processor is configured to define the queue and populate the queue with a plurality of deferrable loads as a function of:
a time the deferrable loads request to be coupled to the distribution transformer; and
at least one of the first operational measurement and the second operational measurement.

7. A system in accordance with claim 1, wherein said processor is configured to:
permit deferrable loads in the queue to couple to the distribution transformer at the discretion of a user;
determine present loading of the distribution transformer above rated load; and
determine a pricing for overloading the distribution transformer.

8. A method of assembling a distribution transformer deferrable load enhancement (DTDLE) system, said method comprising:
providing a distribution transformer;
coupling the distribution transformer to at least one deferrable load positioned on at least one customer premises;
coupling a computing device that includes a processor and memory device coupled to the processor to the distribution transformer and the at least one customer premises; and
configuring the computing device to:
record a first operational measurement of the distribution transformer that is configured to transmit electric power to the at least one deferrable load;
record a second operational measurement of the at least one deferrable load; and
determine a priority of energization of the at least one deferrable load within a queue as a function of at least one of the first operational measurement and the second operational measurement.

9. A method in accordance with claim 8, wherein configuring the computing device to record a first operational measurement of the distribution transformer comprises configuring the computing device to record at least one of:
a value of electric power transmitted through the distribution transformer;
an ambient temperature value; and
an oil temperature value of the distribution transformer; and
a winding temperature value of the distribution transformer.

10. A method in accordance with claim 8, wherein configuring the computing device to record a second operational measurement of the at least one deferrable load comprises configuring the computing device to record at least one of:
a status of the at least one deferrable load;
a value of present real electric power draw;
a previous high value of real electric power draw; and
an operational mode of the at least one deferrable load.

11. A method in accordance with claim 10, wherein configuring the computing device to record a status of the at least one deferrable load comprises at least one of:
configuring the computing device to record a first status, wherein the deferrable load is not coupled to the distribution transformer and is not drawing electric power therefrom; and
configuring the computing device to record a second status, wherein the deferrable load is coupled to the distribution transformer and is drawing at least some electric power therefrom.

12. A method in accordance with claim 10, wherein configuring the computing device to record an operational mode of the at least one deferrable load comprises at least one of:
configuring the computing device to record a first operational mode, wherein the at least one deferrable load draws varying values of electric power from the distribution transformer; and
configuring the computing device to record a second operational mode, wherein the at least one deferrable load only draws electric power at its rated capacity from the distribution transformer.

13. A method in accordance with claim 8, wherein configuring the computing device to determine a priority of energization of the at least one deferrable load within a queue comprises configuring the computing device to define the queue and populate the queue with a plurality of deferrable loads as a function of:
a time the deferrable loads request to be coupled to the distribution transformer; and
at least one of the first operational measurement and the second operational measurement.

14. An electric power distribution system comprising:
at least one distribution transformer;
at least one deferrable load positioned on at least one customer premises and coupled to said at least one distribution transformer;
a memory device configured to store a plurality of operational measurements of said at least one distribution transformer and said at least one deferrable load; and
a processor coupled in communication with said memory device, said processor programmed to:
record a first operational measurement of said at least one distribution transformer that is configured to transmit electric power to said at least one deferrable load;
record a second operational measurement of said at least one deferrable load; and
determine a priority of energization of said at least one deferrable load within a queue as a function of at least one of the first operational measurement and the second operational measurement.

15. An electric power distribution system in accordance with claim 14, wherein the first operational measurement of said at least one distribution transformer comprises at least one of:
a value of electric power transmitted through said at least one distribution transformer;
an ambient temperature value;
an oil temperature value of said at least one distribution transformer; and
a winding temperature value of said at least one distribution transformer.

16. An electric power distribution system in accordance with claim 14, wherein the second operational measurement of said at least one deferrable load comprises at least one of:
a status of said at least one deferrable load;
a value of present real electric power draw;
a previous high value of real electric power draw; and
an operational mode of said at least one deferrable load.

17. An electric power distribution system in accordance with claim 16, wherein said status of said at least one deferrable load comprises at least one of:
a first status, wherein said at least one deferrable load is not coupled to said at least one distribution transformer and is not drawing electric power therefrom; and
a second status, wherein said at least one deferrable load is coupled to said at least one distribution transformer and is drawing at least some electric power therefrom.

18. An electric power distribution system in accordance with claim 16, wherein said operational mode of said at least one deferrable load comprises at least one of:
a first operational mode, wherein said at least one deferrable load draws varying values of electric power from said at least one distribution transformer; and
a second operational mode, wherein said at least one deferrable load only draws electric power at its rated capacity from said at least one distribution transformer.

19. An electric power distribution system in accordance with claim 14, wherein said processor is configured to define said queue and populate said queue with a plurality of said deferrable loads as said deferrable loads as a function of:
a time of request to be coupled to said at least one distribution transformer; and
at least one of the first operational measurement and the second operational measurement.

20. An electric power distribution system in accordance with claim 19, wherein said processor is configured to:
permit at least one of said plurality of deferrable loads in said queue to couple to said at least one distribution transformer at the discretion of a user;
determine present loading of said at least one distribution transformer above rated load; and
determine a pricing for overloading said at least one distribution transformer.
